(19) United States
(12) Patent Application Publication
(10) Pub. No.: US 2015/0162498 A1
(43) Pub. Date: Jun. 11, 2015

(54) LIGHT EMITTING DIODE PACKAGE AND METHOD FOR MANUFACTURING THE SAME

(71) Applicant: ADVANCED OPTOELECTRONIC TECHNOLOGY, INC., Hsinchu Hsien (TW)

(72) Inventors: YAU-TZU JANG, Hukou (TW); PIN-CHUAN CHEN, Hukou (TW); LUNG-HSIN CHEN, Hukou (TW); WEN-LIANG TSENG, Hukou (TW); YU-LIANG HUANG, Hukou (TW)

(21) Appl. No.: 14/524,387

(22) Filed: Oct. 27, 2014

(30) Foreign Application Priority Data
Dec. 10, 2013 (CN) 201310660321.X

(51) Int. Cl. H01L 33/38; H01L 33/62; H01L 33/56; H01L 33/44; H01L 33/54

(52) U.S. Cl. CPC H01L 33/38; H01L 33/44; H01L 33/54; H01L 33/56; H01L 33/62; H01L 2933/0016; H01L 2933/0025; H01L 2933/005; H01L 2933/0066

(57) ABSTRACT

A light emitting diode package (LED) includes two electrodes spaced from each other, an insulating layer sandwiched between the two electrodes, an LED die arranged on the two electrodes and electrically connecting therewith, and an encapsulation layer covering the LED die. Each electrode includes a conductive sheet and a plurality of connecting pins connecting to the conductive sheet. A thickness of the connecting pin is smaller than that of the conductive sheet. A top surface of the connecting pin is coplanar with that of the conductive sheet. The LED package further includes a coating layer coating the connecting pin, part of the coating pin is sandwiched between the top surface of the connecting pin and the encapsulation layer.

### FIELD

The subject matter herein generally relates to a lighting emitting diode (LED) package and method for manufacturing the LED package.

### BACKGROUND

LEDS have low power consumption, high efficiency, quick reaction time, long lifetime, and the absence of toxic elements such as mercury during manufacturing. Due to those advantages, traditional light sources are gradually replaced by LEDS.

Conventionally, a plurality of LED dies are packaged firstly and thereby are divided into a plurality of single LED packages by cutting method. The LED packages include two metal electrodes spaced from each other, an LED die mounted on the two electrodes and a resin encapsulation covering the LED die. Each of the electrodes is fore-etched to a conductive sheet. Several connecting pins having a smaller thickness than the conductive sheet are provided for connecting neighboring conductive sheets. The thinner connecting pins are benefit for the cutting process because of a smaller obstruction. The connecting pins are encapsulated by the resin encapsulation during the packaging process. However, because of the differences between the metal connecting pins and the resin encapsulation, the resin encapsulation layer and the metal connecting pins are easily drew to peel off and form gap therebetween by external forces generated in the cutting process, such that a stability of the LED package is decreased.

What is needed, therefore, it is desirable to provide an LED package which can overcome the above-described problems.

### BRIEF DESCRIPTION OF THE DRAWINGS

Implementations of the present technology will now be described, by way of example only, with reference to the attached figures.

FIG. 1 is atop view of a preformed two electrodes in accordance with an exemplary embodiment of the present disclosure.

FIG. 2 is a cross-sectional view of an LED package formed by the two electrodes of FIG. 1.

FIG. 3 is a top view of an LED package of FIG. 2.

FIGS. 4 to 9 are cross-sectional views showing steps of methods for manufacturing the LED package of FIG. 2.

### DETAILED DESCRIPTION

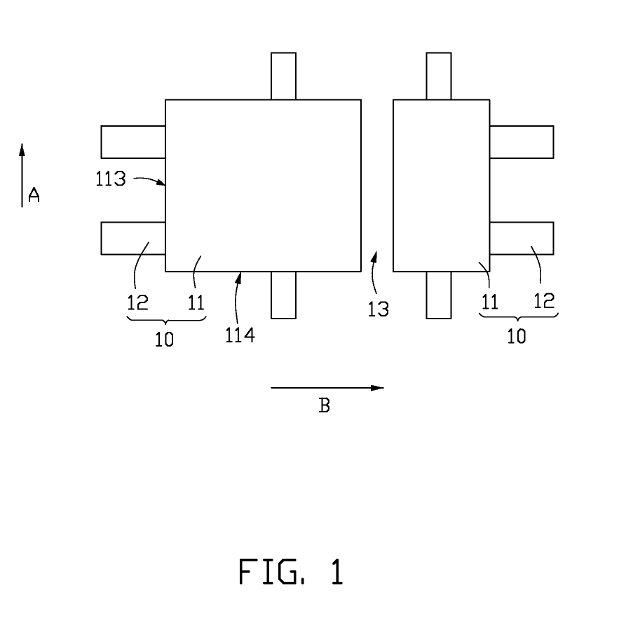

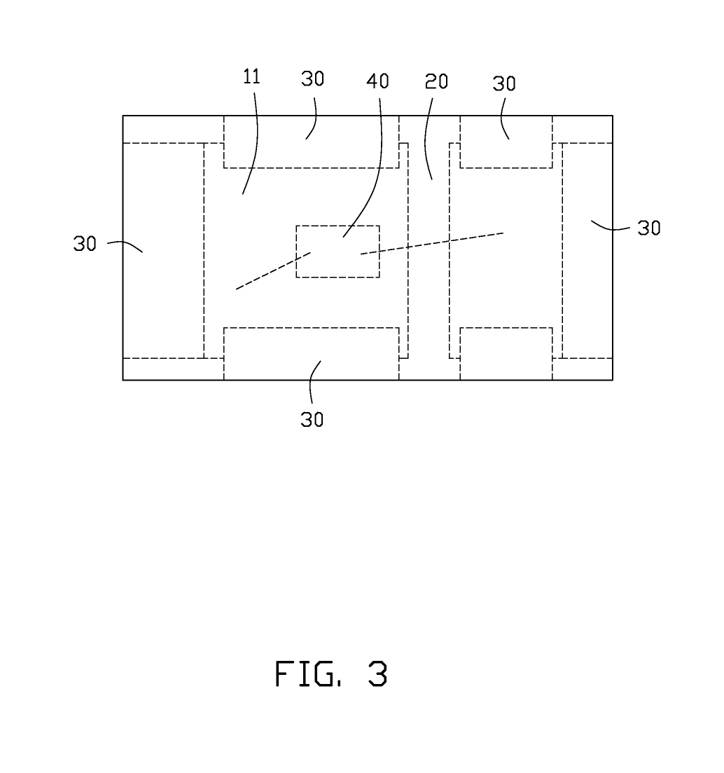

Referring to FIGS. 1 to 3, an LED package 100 in accordance with an exemplary embodiment is provided. The LED package 100 includes two electrodes 10 spaced from each other, an insulating layer 20 sandwiched between the two electrodes 10, a coating layer 30 coated on the two electrodes 10, an LED die 40 arranged on the two electrodes 10 and an encapsulation layer covering the LED die 40.

The two electrodes 10 are made of metal materials. In this embodiment, the two electrodes 10 are made of copper (Cu). Each of the two electrodes 10 includes a conductive sheet 11 and a plurality of connecting pins 12 connected to the conductive sheet 11. In this embodiment, the connecting pins 12 and the corresponding conductive sheet 11 are integrally formed as a single piece.

The conductive sheet 11 has a top surface 111 and a bottom surface 112 opposite to the top surface 111. In this embodiment, the conductive sheet 11 is rectangular. The two conductive sheets 11 are spaced from each other to form a gap 13 for sandwiching the insulating layer 20. The side surfaces of the two conductive sheets 11 adjacent to each other are flat.

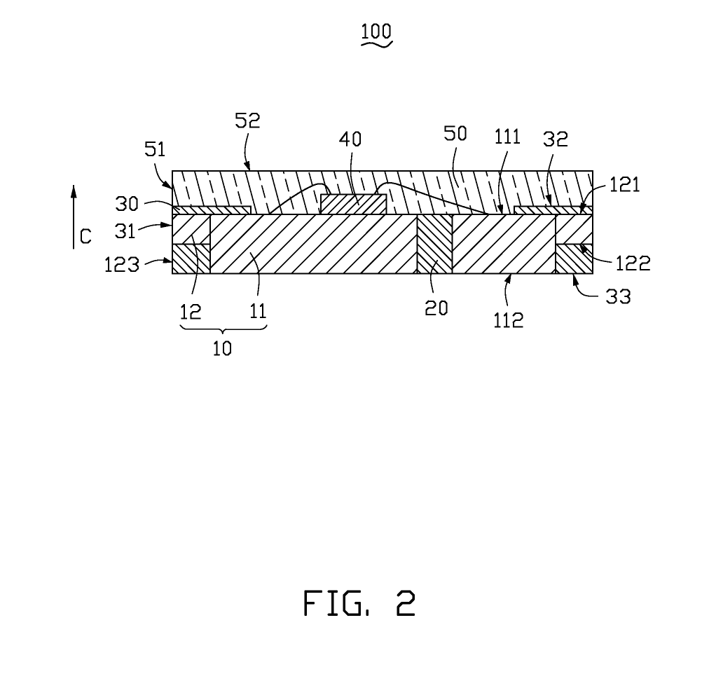

The connecting pins 12 extend outward from lateral side surfaces of each conductive sheet 11. A thickness (a length along the direction shown by arrow C in FIG. 2) of each of the connecting pins 12 is smaller than that of the corresponding conductive sheet 11. A top surface 121 of each connecting pin 12 is coplanar with the top surface 111 of the conductive sheet 11. A bottom surface 122 of the connecting pin 12 is higher than that the bottom surface 112 of the conductive sheet 11. In this embodiment, a thickness of each conductive sheet 12 is half of that of the conductive sheet 11. A width (a length along the direction shown by arrow A in FIG. 1) of each of the connecting pins 12 is smaller than a dimension of corresponding side surface of the conductive sheet 11. In this embodiment, each of the conductive sheets 11 includes a first lateral side surface 113 away from the other conductive sheet 11, and two second later side surfaces 114 parallel from each other. The first lateral side surface 113 is parallel with the width direction A of the LED package 100. The second lateral side surfaces 114 are parallel with a longitudinal direction (as shown by arrow B in FIG. 1) of the LED package 100. There are two connecting pins 12 arranged on the first lateral side surface 113. There is one connecting pin 12 arranged on each of two second lateral side surfaces 114. The connecting pins 12 are configured to connect neighboring conductive sheets 11 for facilitating a mass production of the LED packages.

The insulating layer 20 is arranged in the gap 13 and sandwiched between the two conductive sheets 11 of the two electrodes 10. A top surface of the insulating layer 20 is coplanar with a top surface 111 of the conductive sheets 11. A bottom surface of the insulating layer 20 is coplanar with a bottom surface 112. The insulating layer 20 is made of epoxy molding compound or plastic materials.

The coating layer 30 coats the two electrodes 10. Specifically, the coating layer 30 surrounds the two conductive sheets 11 and coats the connecting pins 12, and the coating layer 30 is full filled in areas between the conductive sheets 11 and the connecting pins 12. A vertical surface 31 of an edge of the coating layer 30 is coplanar with the vertical surface 123 of free ends of the connecting pins 12. The coating layer 30 located at a top surface 121 extends toward the corresponding conductive sheet 11 to cover edges thereof, that is the coating layer covers critical edges of the connecting pins 12 and corresponding conductive sheet 11. A top surface 32 of the coating layer 30 is higher that of the conductive sheet 11. The coating layer 30 covers the bottom surface 122 of the connecting pins 12. A bottom surface 33 of the coating layer 30 is coplanar with the bottom surface 112 of the conductive sheet 11. Such that each of the connecting pins 12 is coated by the coating layer 30 along a thickness direction C of the LED package 100, which prevent the connecting pins 12 from forming extra burs beyond the bottom surfaces 112 of the conductive sheets 11. In this embodiment, the coating layer 30 and the insulating layer 20 are integrally formed as a single piece, that is the coating layer 30 and the insulating layer 20 are made of same materials. Alternatively, the coating layer 30 and the insulating layer 20 can be formed independently. The coating layer 30 can also only coats the connecting pins 12 without being full filled in the areas between the conductive sheet 11 and corresponding connecting pins 12.

The LED die 40 is arranged on an end of one of the electrodes 10 adjacent to the other electrode 10. Specifically, the LED die 40 is arranged on an end of one conductive sheet 11 adjacent to the other conductive sheet 11. The LED die 40 is electrically connected with the two electrodes 10 by wire bonding. Alternatively, the LED die 40 can also be electrically connected with the two electrodes 10 by flip-chip.

The encapsulation layer 50 covers both the LED die 40 and the coating layer 30. The connecting pins 12 are enclosed by the coating layer 30 in a circle around the longitudinal direction B. Part of the coating layer is sandwiched between the top surface 121 of the connecting pins 12 and the encapsulation layer 50. The connecting pins 12 are spaced from the encapsulation layer 50. A vertical surface 51 of edges of the encapsulation layer 50 is coplanar with that of the coating layer 30. The encapsulation layer 50 has a light outputting surface 51 away from the LED die 40. Light generated by the LED die 40 enters that encapsulation layer 50 and radiates out via the light outputting surface 51. The encapsulation layer 50 is made of transparent materials such as colloid different from that of the coating layer 30. In this embodiment, the encapsulation layer 50 is filled with phosphor.

The LED package 100 of this disclosure includes a coating layer 30 coating the connecting pins 12 of the electrodes 10 in a thickness direction C of the LED package 100. Since both materials variances between the coating layer 30 and the encapsulation layer 50, and materials variances between the coating layer 30 and the connecting pins 12 are smaller than materials variances between the encapsulation layer 50 and the connecting pins 12, such that both a denseness between the coating layer 30 and the encapsulation layer 50, and a denseness between the coating layer 30 and the connecting pins 12 are strengthened. When the single LED package 100 is formed by cutting method, the external force can not peel off neither the encapsulation layer 50 and the coating layer 30, nor the coating layer 30 and the connecting pins 12, and a stability of the LED package 100 is correspondingly strengthened.

The disclosure provides a manufacturing method for the LED package 100 which includes the following steps.

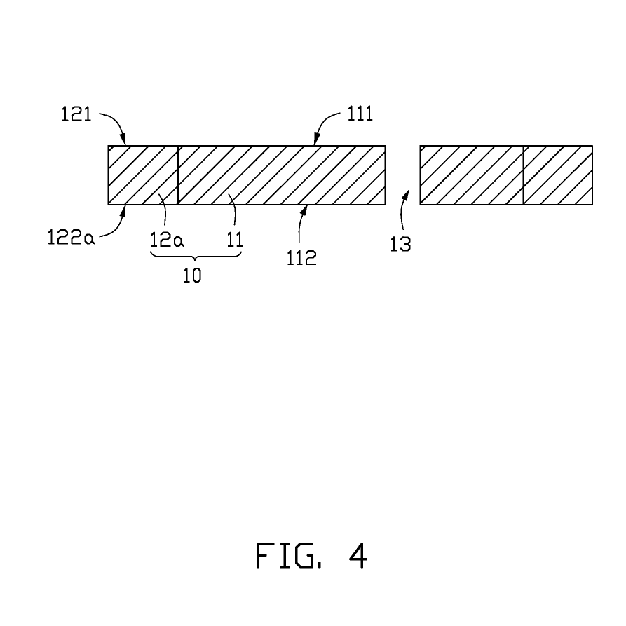

Referring to FIG. 4, two preformed electrodes 10 spaced from each other are provided. Each of the electrodes 10 includes a conductive sheet 11 and a plurality of connecting pins 12a connected to the conductive sheet 11. In this embodiment, the connecting pins 12a and the conductive sheet 11 are integrally formed as a single piece. The electrodes 10 are made of metal materials. The two conductive sheets 11 of the two electrodes 10 are spaced from each other to form a gap 13.

Each of the conductive sheets 11 is rectangular. Each of the conductive sheets 11 has a top surface 111 and a bottom surface 112 opposite to the top surface 111. Each of the connecting pins 12a extends outward from lateral side surfaces of corresponding conductive sheet 11. A width of each of the connecting pins 12a is smaller than that of the corresponding conductive sheet 11. A thickness of each of the connecting pins 12a is equal to that of the corresponding conductive sheet 11, that is a top surface 121a of each connecting pin 12a is coplanar with the top surface 111 of the conductive sheet 11, and a bottom surface 112a of each connecting pin 12a is also coplanar with the bottom surface 112 of the conductive sheet 11. The conductive sheet 11 is rectangular. In this embodiment, each of the conductive sheets 11 includes a first lateral side surface 113 away from the other conductive sheet 11, and two second lateral side surfaces 114 parallel from each other. There are two connecting pins 12 arranged on the first lateral side surface 113. There is one connecting pin 12 arranged on each of two second lateral side surfaces 114.

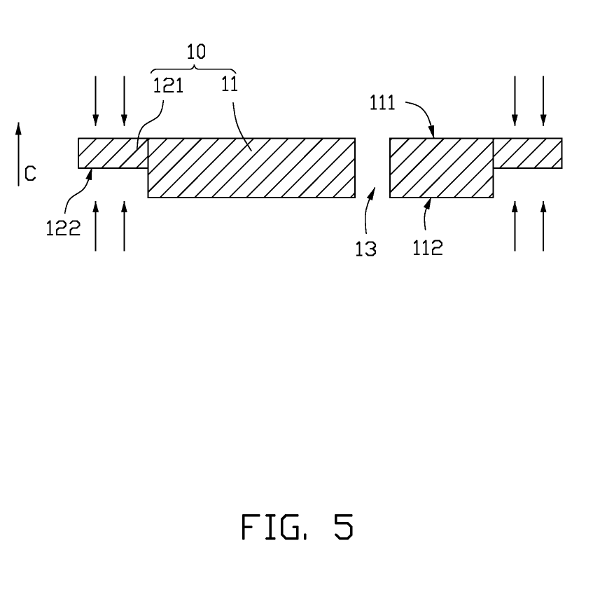

Referring to FIG. 5, each of the connecting pins 12a are etched along a thickness direction C of the electrodes 10 to decrease the thickness of each connecting pin 12a to form the connecting pin 12. Specifically, the bottom surface 122a of each connecting pin 12a is etched. Such that a thickness of each connecting pin 12 is smaller than that of the corresponding conductive sheet 11, that is a top surface 121 of each connecting pin 12 is coplanar with the top surface 111 of the conductive sheet 11, and a bottom surface 122 of each of the connecting pin 12 is higher than that of the bottom surface 112 of the conductive sheet 11.

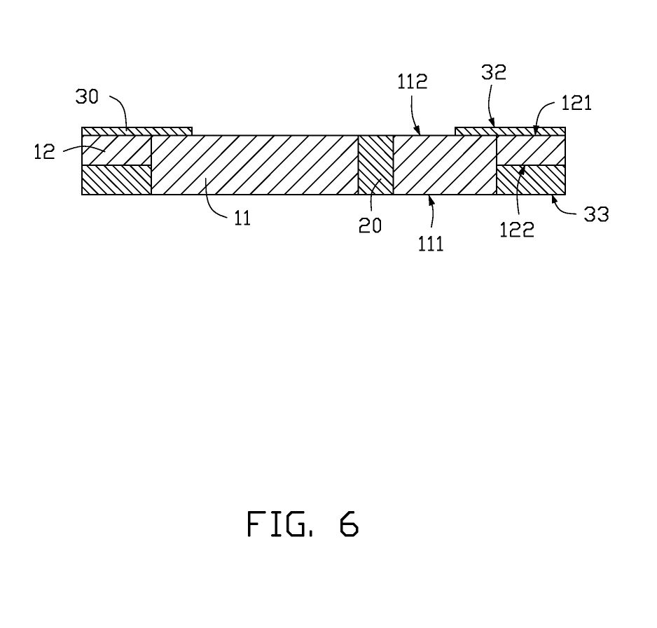

Referring to FIG. 6, an insulating layer 20 is formed in the gap 13 and sandwiched between the two electrodes 10, and a coating layer 30 is formed to coat the two electrodes 10. Specifically, the insulating layer 20 and the coating layer 30 are integrally formed as a single piece by mold. A top surface of the insulating layer 20 is coplanar with the top surface 111 of the conductive sheet 11, and a bottom surface of the insulating layer 20 is coplanar with the bottom surface 112 of the conductive sheet 11. The conductive sheet 11 is surrounded by the coating layer 30 in a circle around the thickness direction C and the connecting pins 12 are coated by the coating layer 30. The coating layer 30 is also full filled in areas between the conductive sheet 11 and the connecting pins 12. A vertical surface 31 of an edge of the coating layer 30 is coplanar with the vertical surface 123 of free ends of the connecting pins 12. A top surface 32 is higher than the top surface 111 of the conductive sheets 11. A bottom surface 33 of the coating layer 30 is coplanar with the bottom surface 112 of the conductive sheet 11.

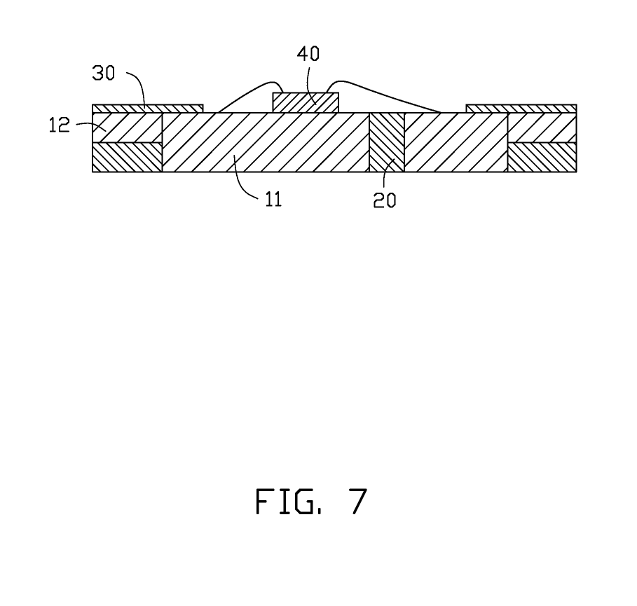

Referring to FIG. 7, an LED die 40 is arranged on an end of one of electrode 10 adjacent to the other electrode 10 by wire bonding. The LED die 40 is electrically connected with the two electrodes 10. Alternatively, the LED die 40 could also be arranged on the two electrodes 10 by flip-chip.

Referring to FIG. 7, an encapsulation layer 50 is formed to cover the LED die 40 and the coating layer 30. The encapsulation layer 50 is made of transparent materials. In this embodiment, the encapsulation layer 50 is filled with phosphor.

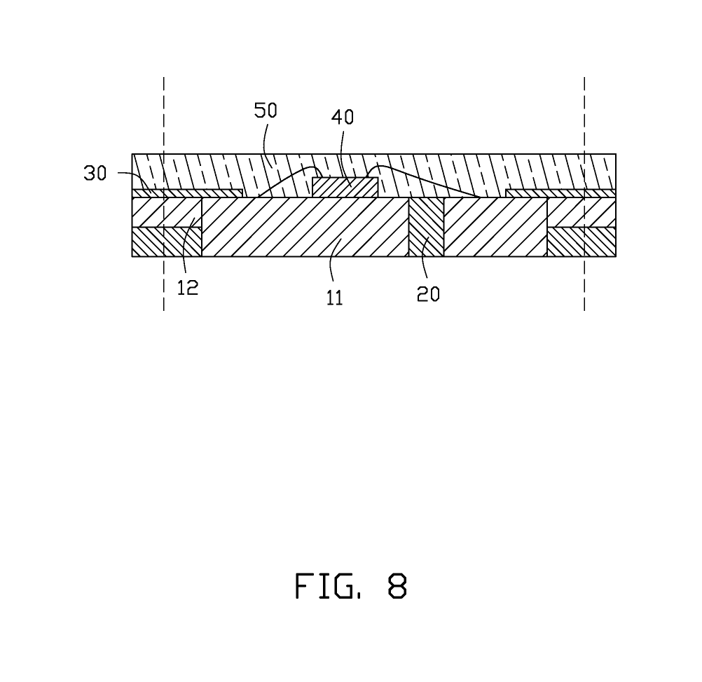

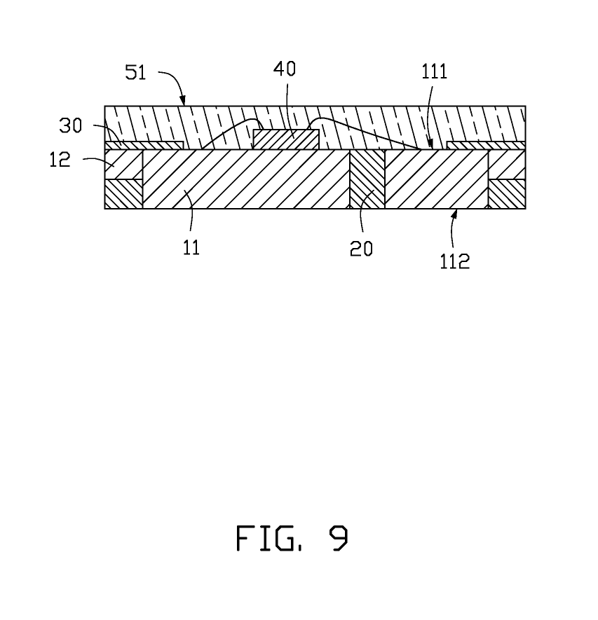

Referring to FIG. 8 to FIG. 9, The LEDS packaged are cut to form a plurality of single LED packages 100. Specifically, part of the encapsulation layer 50, coating layer 30 and connecting pins 12 are removed at a position of the connecting pin 12 along the thickness direction of the LEDS packaged as shown by dotted lines in FIG. 7. A vertical surface 51 of the edge of the encapsulation layer 50 is coplanar with that of the coating layer 30 and the connecting pins 12 are coated by the coating layer, such that a stability of the LED package 100 is strengthened.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A light emitting diode (LED) package comprising:
two electrodes spaced from each other, each of the electrodes comprising a conductive sheet and a plurality of connecting pins connected to the conductive sheet, a width of each of the connecting pins being smaller than that of the corresponding conductive sheet, a thickness of each of the connecting pins being smaller than that of the corresponding conductive sheet, a top surface of the each of the connecting pins being coplanar with that of the corresponding conductive sheet;
a coating layer coating the connecting pins of the electrodes;
an insulating layer sandwiched between the two conductive sheets;
an LED die arranged on the two electrodes, the LED die being electrically connected with the two electrodes; and
an encapsulation layer covering the LED die and the coating layer, part of the coating layer being sandwiched between the top surface of the connecting pins and the encapsulation.

2. The LED package of claim 1, wherein the encapsulation layer and the coating layer are made of different materials.

3. The LED package of claim 2, wherein the encapsulation layer is made of transparent colloid, the coating layer being made of epoxy molding compound or plastic materials, the coating layer and the insulating layer are integrally formed as a single piece and being made of same materials.

4. The LED package of claim 2, wherein the connecting pins extend outward from lateral side surfaces of the corresponding conductive sheet, a top surface of the coating layer being higher than that of the conductive sheets, the connecting pins being spaced from the encapsulation layer.

5. The LED package of claim 4, wherein a bottom surface of each of the connecting pins is higher that of the corresponding conductive sheet, a bottom surface of the coating layer being coplanar with that of the conductive sheets.

6. The LED package of claim 4, wherein a thickness of each of the connecting pins is half of that of the corresponding conductive sheet, the coating layer being full filed in areas between the connecting pins and the corresponding conductive sheet, a vertical surface of edges of the encapsulation layer is coplanar with that of the coating layer.

7. The LED package of claim 4, wherein each of the conductive sheets comprises a first lateral side surface away from the other conductive sheet and two second later side surfaces parallel from each other, the first lateral side surface being parallel with a width direction of the LED package, the second lateral side surfaces being parallel with a longitudinal direction of the LED package, there being two connecting pins arranged on the first lateral side surface, there being one connecting pin arranged on each of two second lateral side surfaces.

8. The LED package of claim 1, wherein each of the connecting pins is coated by the coating layer along a thickness direction of the LED package, the coating layer surrounding the conductive sheets.

9. A method for manufacturing a light emitting diode (LED) comprising steps:
forming two electrodes spaced from each other, each of the electrodes comprising a conductive sheet and a plurality of connecting pins connected to the conductive, a width of each of the connecting pins being smaller than that of the corresponding conductive sheet, the two conductive sheets being spaced from each other to form a gap;
forming an insulating layer and sandwiching the insulating layer between the two conductive sheets of the two electrodes;
forming a coating layer to coat the connecting pins, the coating layer covering a top surface of the connecting pins and extending toward corresponding conductive sheet;
arranging an LED die on the two electrodes, the LED die being electrically connected with the two electrodes;
covering an encapsulation layer on the LED die and the coating layer, part of the coating layer being sandwiched between the top surface of the connecting pins and the encapsulation layer; and
cutting the encapsulation layer, the coating layer and connecting pins at a predetermined position of each of the connecting pins.

10. The method for manufacturing the LED package of claim 9, wherein the coating layer and the encapsulation layer are made of different materials.

11. The method for manufacturing the LED package of claim 10, wherein the encapsulation layer is made of transparent colloid, the coating layer being made of epoxy molding compound or plastic materials, the coating layer and the insulating layer are integrally formed as a single piece and being made of same materials.

12. The method for manufacturing the LED package of claim 10, wherein the connecting pins extend outward from lateral side surfaces of the corresponding conductive sheet, a top surface of the coating layer being higher than that of the conductive sheets.

13. The method for manufacturing the LED package of claim 12 further comprising an etching step, wherein a bottom surface of each of the connecting pins are etched in the etching step, and a bottom surface of each of the connecting pins etched being higher that of the corresponding conductive sheet, a bottom surface of the coating layer being coplanar with that of the conductive sheets.

14. The method for manufacturing the LED package of claim 12, wherein a thickness of each of the connecting pins is half of that of the corresponding conductive sheet, the coating layer being full filed in areas between the connecting pins and the corresponding conductive sheet, a vertical surface of edges of the encapsulation layer is coplanar with that of the coating layer.

15. The method for manufacturing the LED package of claim 12, wherein each of the conductive sheets comprises a first lateral side surface away from the other conductive sheet and two second later side surfaces parallel from each other, the first lateral side surface being parallel with a width direction of the LED package, the second lateral side surfaces being parallel with a longitudinal direction of the LED package, there being two connecting pins arranged on the first lateral side surface, there being one connecting pin arranged on each of two second lateral side surfaces.

16. The method for manufacturing the LED package of claim 9, wherein each of the connecting pins is coated by the coating layer along a thickness direction of the LED package, the coating layer surrounding the conductive sheets.

17. A light emitting diode package comprising:
two electrodes spaced from each other, each of the electrodes comprising a conductive sheet and a plurality of connecting pins electrically connected to the conductive sheet, a width of each of the connecting pins being smaller than a width of the corresponding conductive sheet, a thickness of each of the connecting pins being smaller than a thickness of the corresponding conductive sheet, a top surface of the each of the connecting pins being coplanar with a top surface of the corresponding conductive sheet;
a coating layer coating the plurality of connecting pins of the electrodes;
an insulating layer sandwiched between the two conductive sheets;
a light emitting diode die arranged on at least one electrode, the light emitting diode die being electrically connected with the two electrodes; and
an encapsulation layer covering the light emitting diode die and the coating layer, a portion of the coating layer being sandwiched between the top surface of the connecting pins and the encapsulation.
